(19) United States
(12) Patent Application Publication
(10) Pub. No.: US 2005/0112051 A1
(43) Pub. Date: May 26, 2005

(54) Systems and methods for producing single-walled carbon nanotubes (SWNTS) on a substrate

(75) Inventors: Jie Liu, Chapel Hill, NC (US); Shaoming Huang, Durham, NC (US); Qiang Fu, Durham, NC (US)

Correspondence Address: JENKINS, WILSON & TAYLOR, P. A., 3100 TOWER BLVD, SUITE 1400, DURHAM, NC, 27707, US

(73) Assignee: Duke University

(21) Appl. No.: 10/759,592

(22) Filed: Jan. 16, 2004

Related U.S. Application Data
(60) Provisional application No. 60/440,781, filed on Jan. 17, 2003.

(51) Int. Cl. B01J 21/08; B01J 21/12; B01J 21/14; D01F 9/12; C23C 16/00; B05D 3/04

(52) U.S. Cl. 423/447.1; 502/232; 427/301; 427/249.1; 427/282

(57) ABSTRACT

According to one embodiment, a method of fabricating a nanotube on a substrate is provided. The method can include a step for attaching a catalyst to a substrate. The method can also include a step for heating the catalyst to a predetermined temperature such that a nanotube grows from the catalyst. Further, the method can include a step for directing a feeding gas over the catalyst in a predetermined direction such that the nanotube grows in the predetermined direction.

### RELATED APPLICATIONS

This application claims the benefit of U.S. patent application Ser. No. 60/440,781, filed Jan. 17, 2003, the disclosure of which is incorporated herein by reference in its entirety.

### GRANT STATEMENT

This invention was supported by National Aeronautics and Space Administration (NASA) grant NAG-1-01061 and Army Research Office (ARO) grant DAAD19-00-1-0548. Thus, the Government has certain rights in this invention.

### TECHNICAL FIELD

The present invention relates to systems and methods for producing nanotubes on a substrate. More particularly, the present invention relates to methods and systems for controlling the position, alignment, orientation, and length of nanotubes produced on a substrate.

### BACKGROUND ART

Nanotubes, particularly carbon single-walled nanotubes (SWNTs), are useful systems for investigating fundamental electronic properties and for use as building blocks for molecular electronics because of their small size, unique low-dimensional structure, and electronic properties. Some nanoelectronic devices based on individual SWNTs include quantum wires, field-effect transistors, logic gates, field emitters, diodes, and inverters. For applications in nanoelectronics, the capability to control the locations and orientations of nanotubes is important for large-scale fabrications of devices. SWNTs can also be utilized for producing high strength composite materials. For application to high strength composite materials, lengthy nanotubes can improve the load transfer between an individual nanotube and a nanotube matrix.

Currently, nanodevices made of individual SWNTs can be prepared by either depositing a suspension of purified bulk nanotube samples on a substrate or by directly growing individual nanotubes on a substrate with chemical vapor deposition (CVD). The first approach suffers from the presence of more defects and altered electrical properties of the nanotubes due to the use of highly oxidative chemicals and the sonification process during purification and suspension processes. The CVD method includes advantages in terms of low temperature, large-scale production and controllability. Much effort has been made to successfully grow SWNTs on surfaces by using isolated catalytic nanoparticles or identical clusters.

Some progress has been made in controlling nanotube orientation when growing SWNTs with CVD. For example, electric fields have been used to grow and align suspended SWNTs and SWNTs on flat surfaces. Additionally, electric fields based on the CVD of ethylene have been used for vectorial growth of SWNT arrays on a surface. However, the introduction of a strong electric field during the growth of nanotubes is not an easy task. Furthermore, organizing SWNTs arrays into multidimensional crossed-network structures in a controllable manner has not been demonstrated.

In view of the known methods for fabricating nanotubes, it is desirable to have an improved method and system for fabricating nanotubes. It is also desirable to provide a method for fabricating lengthy nanotubes. Additionally, it is desirable to provide fabrication methods having improved control of the location and orientation of SWNTs produced on substrates. It is also desirable to provide an improved method and system for producing organized SWNT arrays in large-scale, carbon nanotube-based nanodevice.

### SUMMARY

According to one embodiment, a method of fabricating a nanotube on a substrate is provided. The method can include a step for attaching a catalyst to a substrate. The method can also include a step for heating the catalyst to a predetermined temperature such that a nanotube grows from the catalyst. Further, the method can include a step for directing a feeding gas over the catalyst in a predetermined direction such that the nanotube grows in the predetermined direction.

According to a second embodiment, a method of fabricating a nanotube on a substrate is provided. The method can include a step for attaching a catalyst to a substrate. The method can also include a step for heating the catalyst to about between about 800° C. and 1050° C. between about 10 and 20 minutes such that a nanotube grows from the catalyst. Further, the method can include a step for directing a feeding gas over the catalyst in a predetermined direction such that the nanotube grows in the predetermined direction.

According to a third embodiment, a system for fabricating a nanotube on a substrate is provided. The system can include a substrate comprising a catalyst attached thereto. The system can also include a furnace operable to heat the catalyst to a predetermined temperature such that a nanotube grows from the catalyst. Further, the system can include a gas blower operable to direct a feeding gas over the catalyst in a predetermined direction such that the nanotubes grow in the predetermined direction.

According to a fourth embodiment, a system for fabricating a nanotube on a substrate is provided. The system can include a substrate comprising a catalyst attached thereto. The system can also include a furnace operable to heat the catalyst to between about 800° C. and 1050° C. between about 10 and 20 minutes such that a nanotube grows from the catalyst. Further, the system can include a gas blower operable to direct a feeding gas over the catalyst in a predetermined direction such that the nanotubes grow in the predetermined direction.

According to a fifth embodiment, a method of fabricating a nanotube on a substrate is provided. The method can include a step for attaching a first catalyst to a substrate. The method can also include a step for heating the first catalyst to a first predetermined temperature such that a first nanotube grows from the first catalyst. Further, the method can include a step for directing a first feeding gas over the first catalyst in a first predetermined direction such that the first nanotube grows in the first predetermined direction. The method can also include a step for attaching a second catalyst to the substrate. The method can also include a step for heating the second catalyst to a second predetermined temperature such that a second nanotube grows from the first catalyst. Further, the method can include a step for directing a second feeding gas over the second catalyst in a second predetermined direction such that the second nanotube grows in the second predetermined direction. The second predetermined direction is a different direction than the first predetermined direction.

According to a sixth embodiment, a system for fabricating nanotubes on a substrate is provided. The system can include a substrate comprising a first and second catalyst attached thereto. The system can also include a furnace operable to heat the first catalyst to a first predetermined temperature such that a first nanotube grows from the first catalyst. The furnace can also be operable to heat the second catalyst to a second predetermined temperature such that a second nanotube grows from the second catalyst. The system can also include a gas blower operable to direct a first feeding gas over the first catalyst in a first predetermined direction such that the first nanotube grows in the first predetermined direction. The gas blower can also be operable to direct a second feeding gas over the second catalyst in a second predetermined direction such that the second nanotube grows in the second predetermined direction. The second predetermined direction can be a different direction than the first predetermined direction.

According to a seventh embodiment, a method of fabricating nanotubes on a substrate is provided. The method can include a step for providing a substrate comprising a surface and a plurality of suspension structures attached to the surface. The suspension structures can be separated by an area of the surface of the substrate. The method can also include a step for attaching a first plurality of catalysts to the surface area of the substrate between the separated suspension structures. Further, the method can include a step for heating the first plurality of catalysts to a first predetermined temperature such that a first plurality of nanotubes grow from the first plurality of catalysts. The method can also include a step for directing a first feeding gas over the first plurality of catalysts in a first predetermined direction such that the first plurality of nanotubes grow in the first predetermined direction. Further, the method can include a step for attaching a second plurality of catalysts to the plurality of suspension structures. The method can also include a step for heating the second plurality of catalysts to a second predetermined temperature such that a second plurality of nanotubes grow from the first plurality of catalysts. The method can also include a step for directing a second feeding gas over the second plurality of catalysts in a second predetermined direction such that the second plurality of nanotubes grow in the second predetermined direction. The second predetermined direction can be a different direction than the first predetermined direction.

Some of the objects of the invention having been stated hereinabove, and which are addressed in whole or in part by the present invention, other objects will become evident as the description proceeds when taken in connection with the accompanying drawings as best described hereinbelow.

### BRIEF DESCRIPTION OF THE DRAWINGS

Exemplary embodiments of the subject matter will now be explained with reference to the accompanying drawings, of which:

FIG. 1A is a cross-sectional side view of a substrate for fabricating an SWNT array;

FIG. 1B is a cross-sectional side view of a substrate having catalysts dispersed on a top surface thereof;

FIG. 1C is a cross-sectional side view of a substrate during the growth, or synthesis, of nanotubes from catalysts;

FIG. 2 is a scanning electron microscope (SEM) image of a side view of a substrate having SWNTs fabricated thereon;

FIG. 3 is a schematic diagram of exemplary stages of a substrate undergoing a fast heating process;

FIG. 4A is an SEM image of a top view of a substrate with SWNTs fabricated thereon, wherein the SWNTs have been produced according to a fast heating embodiment with CO/H₂ flow and a reaction temperature of about 900° C.;

FIG. 4B is a composite of different SEM images showing two millimeter long nanotubes;

FIG. 4C is another SEM image of a magnified top view of SWNTs aligned along a controlled angle (about 30°) with respect to the edge of a catalyst island;

FIG. 4D is an SEM image of a top view of nanotubes that have been cut by running a blade across the nanotubes;

FIG. 4E is an SEM image of a top view of nanotubes extending between catalyst islands;

FIG. 4F is an SEM image of a top view of a catalyst island pattern on a SiO₂/Si wafer before nanotube growth;

FIG. 4G is an SEM image of a top view of the catalyst island pattern shown in FIG. 4F after nanotube growth;

FIG. 4H is an SEM image showing that the nanotubes terminate at a free end because there is no additional catalyst pattern downstream of the gas flow exists;

FIG. 41 is an SEM image of SWNTs grown using a fast heating process with Fe/Mo nanoparticles;

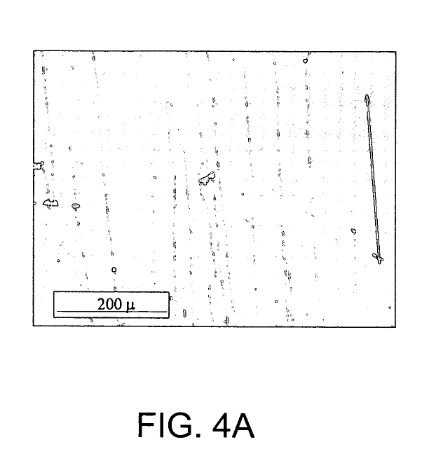

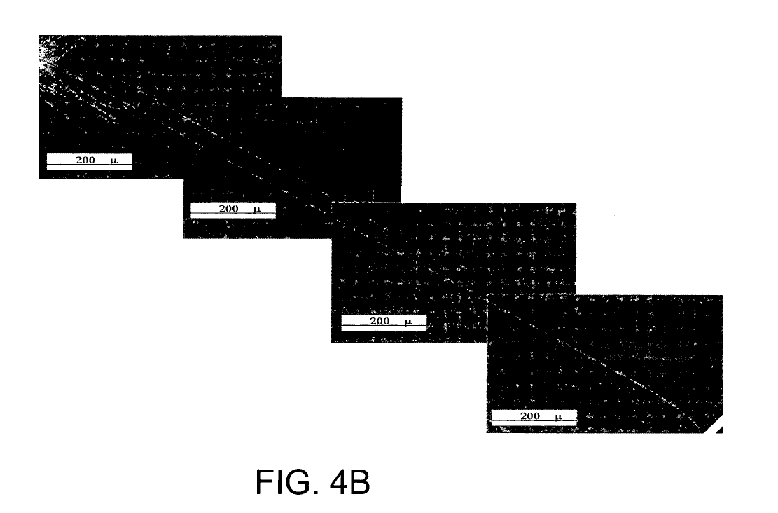

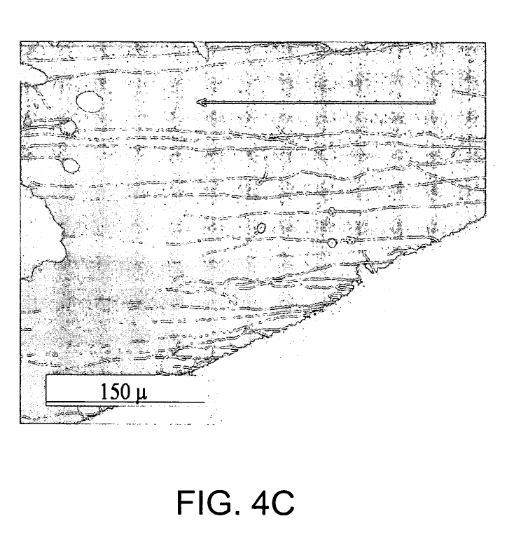

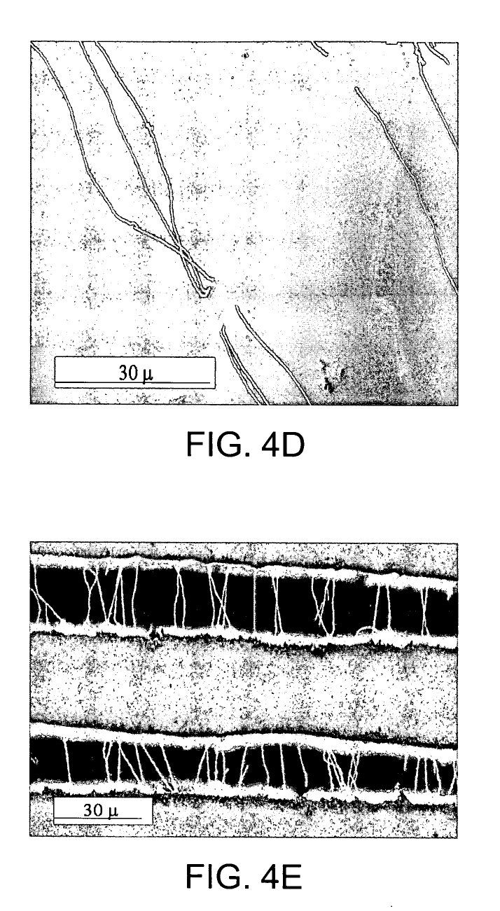

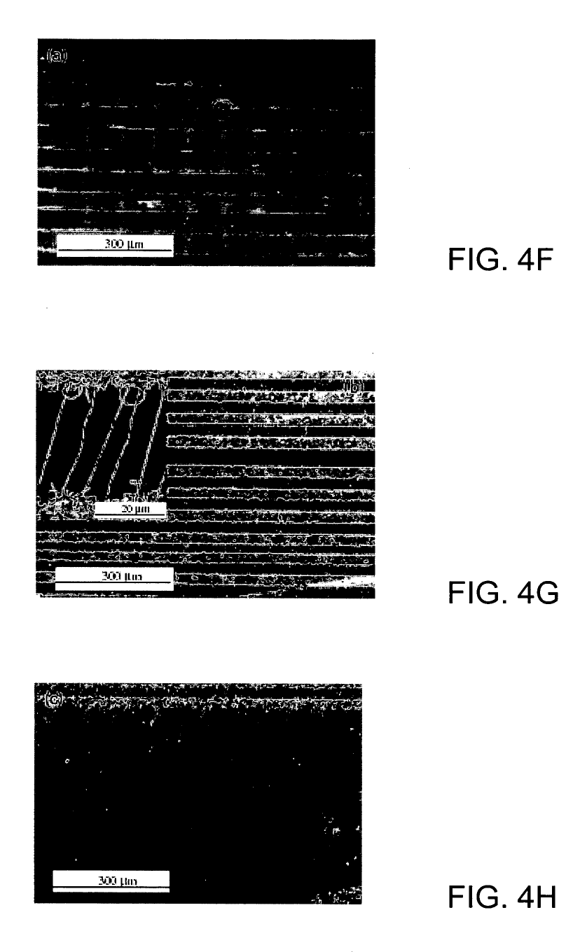

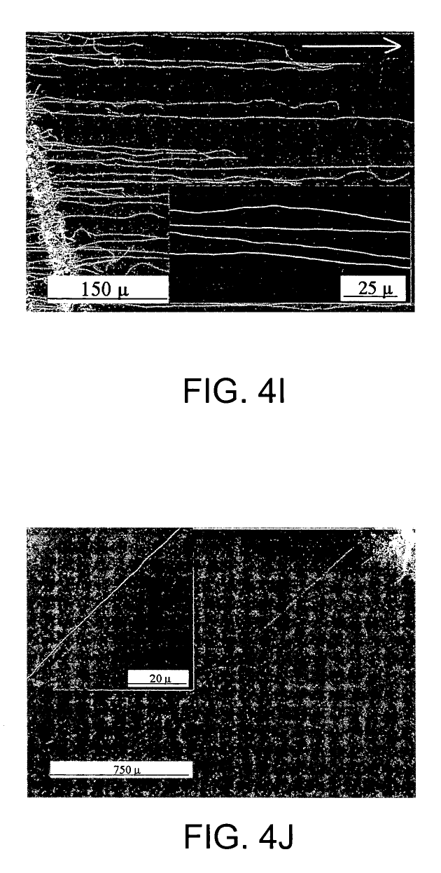

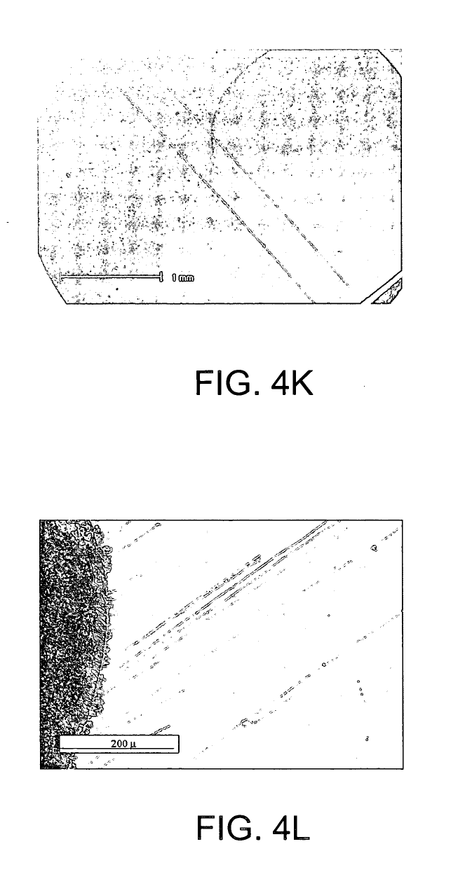

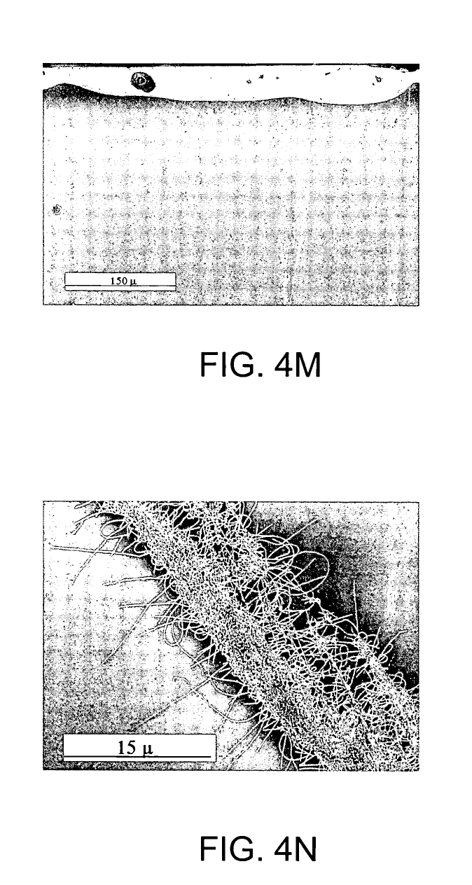

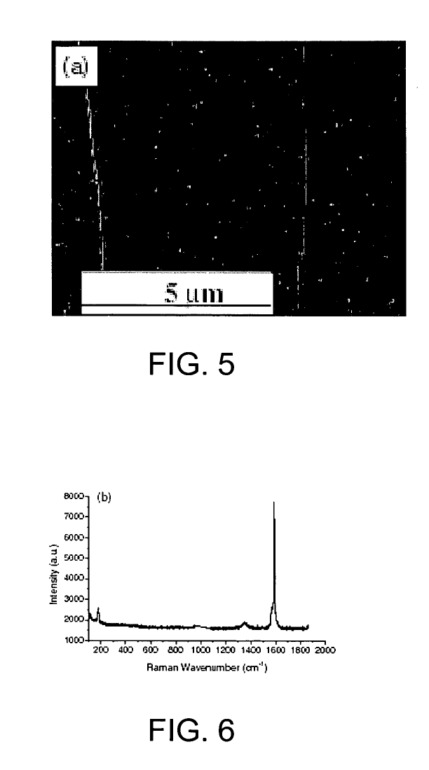

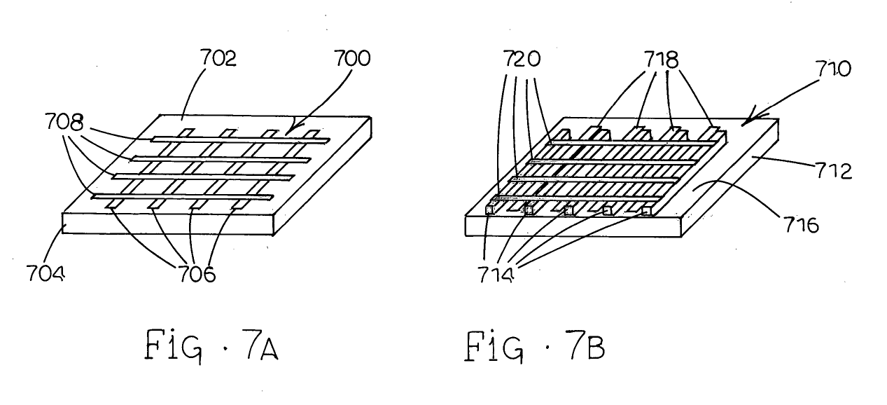

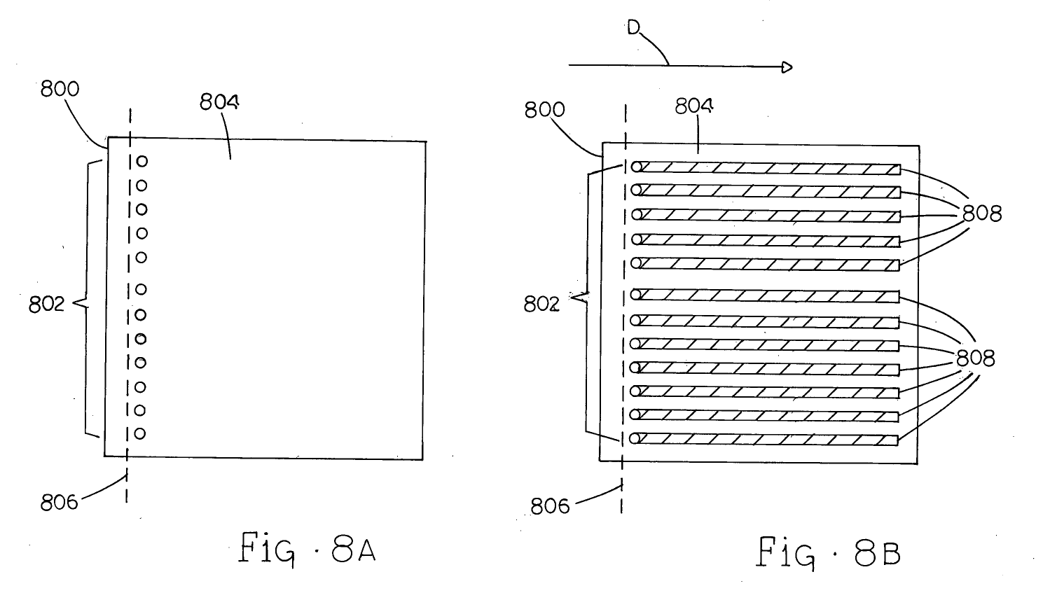

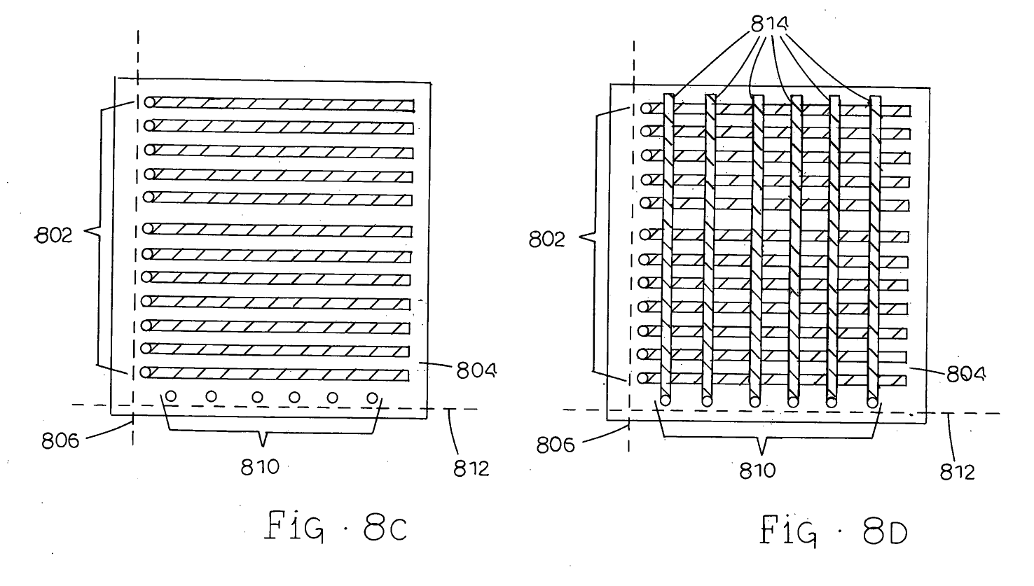

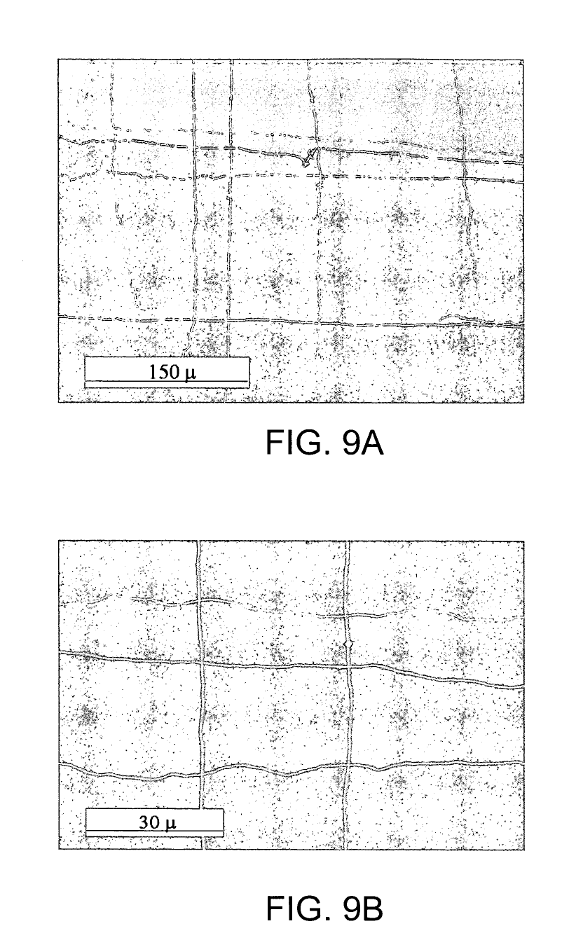

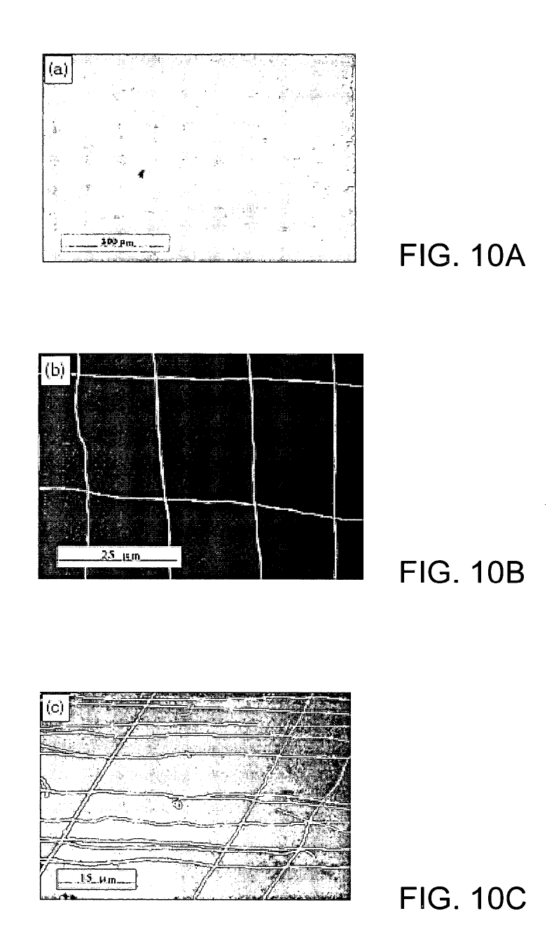

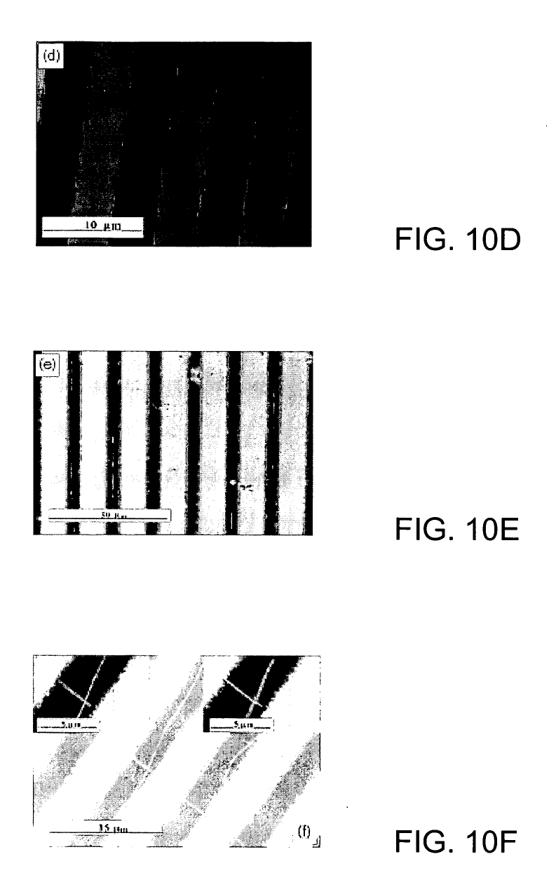

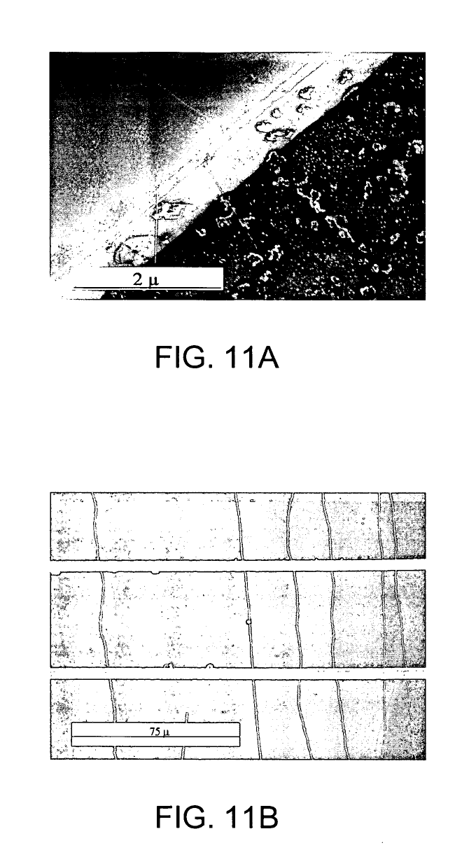

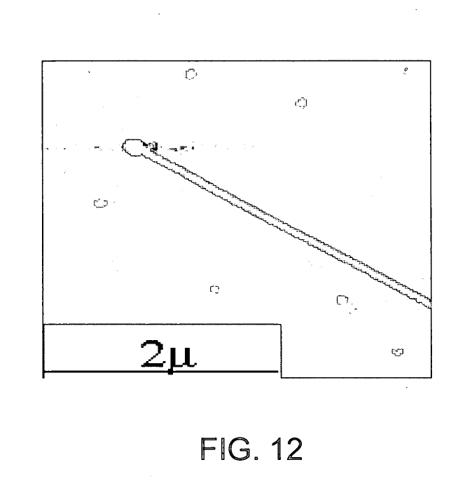

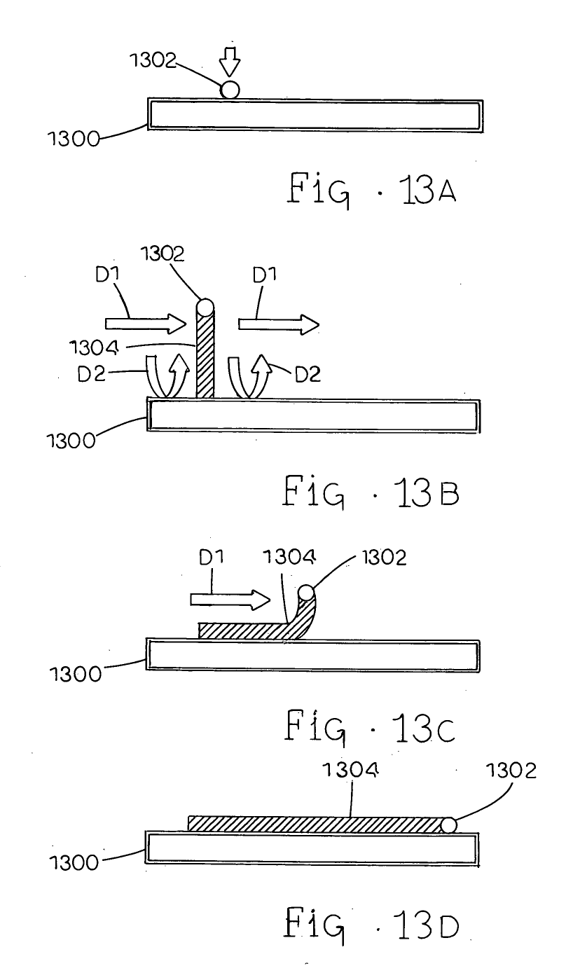

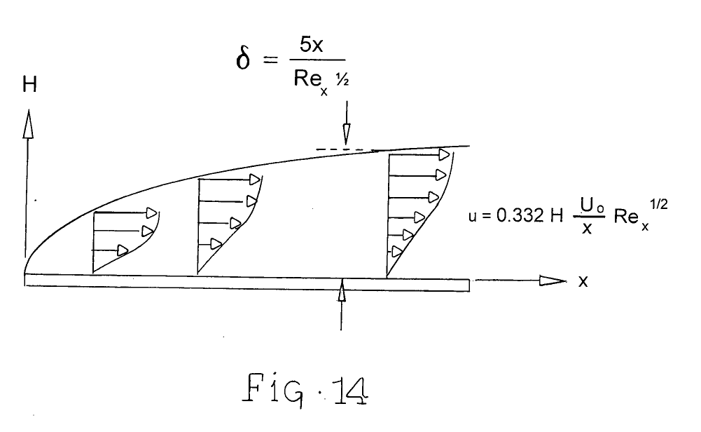

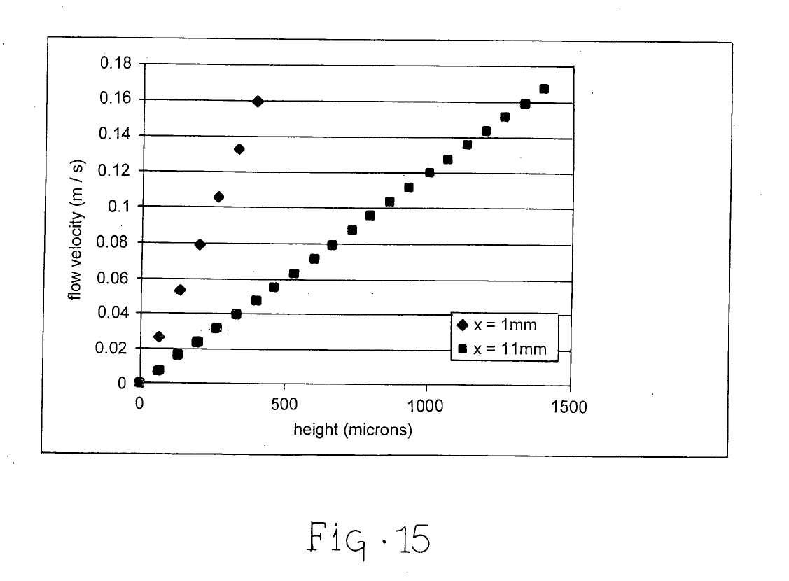

FIG. 4J is an SEM image of a 2.1 millimeter straight SWNT grown according to a fast heating process;

FIG. 4K is an SEM image of several individual SWNTs aligned parallel to one another grown according to a fast heating process;

FIG. 4L is an SEM image of several SWNTs grown using an Fe/Mo molecular cluster, CO/H₂ gas, at 900° C. for about 10 minutes;

FIG. 4M is an SEM image of several long SWNTs grown using Fe/Mo nanoparticles, C H₂OH/H₂/Ar, at about 900° C. for about 10 minutes;

FIG. 4N is an SEM image of random short SWNTs grown with a slow heating technique;

FIG. 5 is an atomic force microscopy (AFM) image showing SWNTs grown using a fast heating process;

FIG. 6 is a Raman spectrum chart of the as-synthesized ultralong SWNT arrays shown in FIG. 5;

FIG. 7A is a perspective view of crossed network of SWNT arrays attached to a surface of a substrate;

FIG. 7B is a perspective view of crossed network of SWNT arrays attached to a substrate including suspension structures;

FIGS. 8A-8D are views of different stages in the fabrication of crossed network of SWNT arrays;

FIG. 9A is an SEM image of a top view of a substrate having a two-dimensional nanotube network fabricated thereon;

FIG. 9B is another SEM image of a magnified top view of the SEM image shown in FIG. 9A;

FIG. 10A is an SEM image of a multi-layer crossed network of SWNTs;

FIG. 10B is another SEM image of another multi-layer crossed network of SWNTs;

FIG. 10C is an SEM image of nanotube arrays with a 60° angle between one another;

FIG. 10D is an AFM image of a top view of a suspension structure on a substrate surface before different suspend, crossed nanotube arrays are grown;

FIG. 10E is an AFM image of a top view of the suspension structure shown in FIG. 10D after different suspend, crossed nanotube arrays are grown;

FIG. 10F is a magnified AFM image of the suspension structure with nanotubes arrays shown in FIG. 10E;

FIGS. 11A and 11B are exemplary SEM images showing nanotubes that have grown over a barrier on the substrate and across trenches;

FIG. 12 is an AFM image showing a long nanotube having a nanoparticle at its tip;

FIGS. 13A-13D are different stages in the fabrication of a nanotube on a substrate for demonstrating the “kite-mechanism”;

FIG. 14 is a chart of height versus distance along a substrate surface showing the flow velocity of a nanotube distributed above a flat substrate;

FIG. 15 is a plot chart of flow velocity as a function of height at two different locations on a flat substrate;

FIG. 16 is an SEM image of a high density of well-oriented SWNT arrays, including a 10 micrometer scale for size reference; and

FIG. 17 is an AFM image of nanotubes without catalysts on their tips and near a catalyst island.

### DETAILED DESCRIPTION OF THE INVENTION

Methods and systems are described herein for fabricating lengthy, well-aligned SWNTs on a substrate. Methods and systems are also described herein for accurately controlling nanotube alignment, orientation, length and location. These methods and systems are described with regard to the accompanying drawings. It should be appreciated that the drawings do not constitute limitations on the scope of the disclosed methods and systems.

As referred to herein, the term “carbon nanotube” or “nanotube” means a structure at least partially having a cylindrical structure mainly comprising carbon.

### Aligning Nanotubes

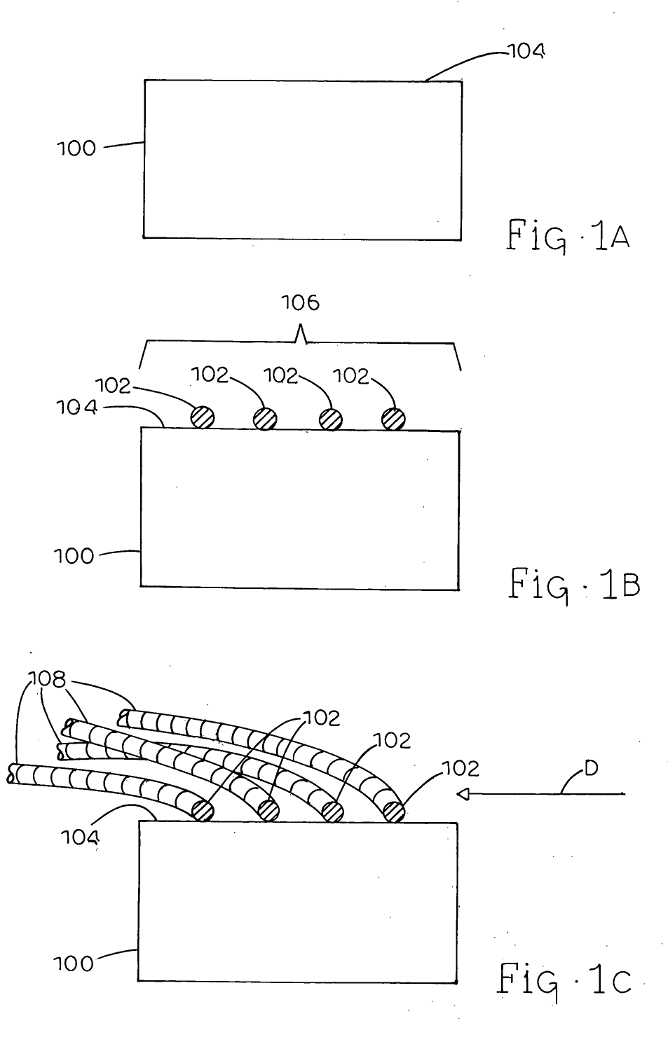

Well-aligned and well-isolated SWNT arrays can be directly grown on a substrate surface using monodispersed nanoparticles as catalysts, a fast heating process, and a directed feeding gas. Referring to FIGS. 1A-1C, views of different stages in the fabrication of an SWNT array on a substrate are illustrated. FIG. 1A illustrates a cross-sectional side view of a substrate 100 for fabricating an SWNT array. Substrate 100 can comprise a SiO₂/Si wafer. Substrate 100 can also comprise a p-doped silicon wafer with 100 nanometer-thick thermal oxide and quartz glass, or a 600 nanometer thick layer of SiO₂. Alternatively, substrate 100 can comprise another suitable substrate such as an alumina substrate or MgO substrate for fabrication of nanotubes.

According to one embodiment, a microcontact printing process can be utilized to pattern substrate 100 for dispersion of catalysts 102 (shown in FIG. 1B). For example, substrate 100 can be a p-doped silicon wafer with thermally grown oxide. Substrate 100 can be cleaned by ultrasonification in isopropanol, followed by oxidative cleaning in a UV/ozone or in a 2:1H₂SO₄/H₂O₂ pirhana solution. About 1 to 4 nanometers of titanium (Ti), followed by about 50 to 200 nanometers of silver (Ag), can be thermally evaporated onto the silicon oxide surface. Alkanethiol resist patterning and pattern transfer can be implemented via a process known to those of skill in the art. Briefly, patterned poly(dimethylsiloxame) (PDMS) stamps can be inked with 0.5 mM octadecanethiol solution in ethanol and blown dry with fluorocarbon gas. The stamps can then be placed in conformal contact with the silver surface and removed after between about 10 and 15 seconds. The alkanethiol-patterned substrate 100 can then be placed in an aqueous etching solution consisting of 0.1 M K₂S₂O₃, 0.01 M K₃FeCN₆, and 0.001 M K₄FeCN₆ for about 10 to 20 seconds or until etching is complete. The resulting silver patterns can be transferred to the underlying silicon oxide by etching for about 20 seconds in an HF/NH₄F etching solution consisting of 25 milliliters water (having a resistance greater than 18 MΩ), 14 milliliters 48% HF, and 6.5 g NH₄F. The remaining Ti/Ag patterns can be removed by extended exposure to the ferri-/ferrocyanide etchant followed by immersion in unbuffered 5% HF for between about 1 and 2 seconds. Substrate 100 can then be treated with UV/ozone and used for SWNT growth.

After preparation of substrate 100, SWNTs can be grown by chemical vapor deposition. According to one embodiment, SWNTs can be grown by carbon monoxide-chemical vapor deposition (CO-CVD) in a two-furnace system. One furnace of the two-furnace system can pretreat carbon monoxide gas at about 700° C. for subsequent use as described below. The other furnace can be used to heat substrate 100 for facilitating nanotube growth from catalysts 102 (shown in FIG. 1B). FIG. 1B illustrates a cross-sectional side view of substrate 100 having catalysts 102 dispersed on a top surface 104 thereof. Catalysts 102 can be dispersed or patterned via photolithography or simple deposition on surface 104. According to one embodiment, catalysts 102 can be either directly deposited on the substrate from their hexane solution or patterned by a photolithographic technique. Catalysts 102 can also be placed via electrochemical deposition, chemical deposition, electrooxidation, electroplating, sputtering, thermal diffusion and evaporation, physical vapor deposition, and sol-gel deposition. Further, catalysts 102 can also be positioned by simple drying of a solution containing catalysts 102, or ink-jet printing of a solution containing catalysts 102. Catalysts 102 can also be positioned on other suitable surfaces of substrate 100 or surfaces attached to substrate 100.

Catalysts 102 can comprise iron/molybdenum (Fe/Mo) nanoparticles, iron nanoparticles, iron/platinum (Fe/Pt) nanoparticles, molecular clusters containing Fe and Mo, or pure Fe. The nanoparticles can have diameters between about 1 and 6 nanometers. According to one embodiment, catalysts 102 comprising monodispersed Fe/Mo nanoparticles can be synthesized by thermal decomposition of Fe(CO)₅/Mo(CO)₆ under the protection of surfactant. Collectively catalysts 102 can form a catalyst island, generally designated 106, on surface 104. According to one embodiment, substrate 100 can be exposed to an ultraviolet/ozone treatment at room temperature for removing any organic coating on catalysts 102. Alternatively, substrate 100 can be annealed at 1100° C. for about 10 minutes for removing any organic coating on catalysts 102. Next, substrate 100 can be reduced in Ar/H₂ (1000 sccm (standard cc per minute)/200 sccm) at 700° C. for about 5 minutes.

According to an alternative embodiment, catalysts (such as catalysts 102 shown in FIGS. 1B and 1C) can be patterned on a substrate (such as substrate 100 shown in FIGS. 1A-1C) by first spin coating a layer of photoresist (such as SHIPLEY® 1813 photoresist available from Shipley Inc. of Marlborough, Mass.) on the substrate and then drying the substrate at 100° C. for about 5 minutes. A film-type, high contrast, white-black film having parallel line pattern with different resolution can be used as a photomask. The substrate can be exposed to ultra-violet light for about 3 to 5 minutes and then developed in about 2% to 3% tetramethylammonium hydroxide aqueous solution for about 1 to 2 minutes. A hexane solution can then be dropped on the patterned substrate. After drying at room temperature, the substrate can be further developed in 1 M NaOH aqueous solution to remove photoresist on the substrate. The catalyst pattern suitable for nanotube growth remains located on the photoresist-free regions.

FIG. 1C illustrates a cross-sectional side view of substrate 100 during the growth, or synthesis, of nanotubes 108 from catalysts 102. An array of nanotubes 108 on substrate 100 can form from catalyst island 106. Substrate 100 can be positioned in the second furnace of the two-furnace system for nanotube growth. Nanotubes 108 can be synthesized by feeding a suitable gas over catalysts 102 in a direction indicated by direction arrow D. The feeding gas can comprise a CO/H₂ mixture, hydrocarbons, alcohols, hydrocarbon/H₂ mixture, or alcohol/H₂ mixture. Nanotubes 108 can be aligned in the direction indicated by direction arrow D due to the gas flow in the same direction during the growth of nanotubes 108. Thus, the orientation of nanotubes 108 can be directly controlled by the direction of gas flow in a CVD system. Additionally, nanotubes 108 can be grown via a fast heating process by moving substrate 100 to the center of a furnace preheated to 900° C., applying a suitable gas flow in the desired direction for alignment, and maintaining the temperature of the furnace at 900° C. for between about 10 and 20 minutes. Alternatively, the furnace can be set between about 800° C. and 1050° C. According to an alternative embodiment, nanotubes 108 can be grown by heating substrate 100 at 900° C. under CO/H₂ mixture (800 sccm/200 sccm) for 10 minutes.

Alternative to utilizing gas flow for aligning nanotubes, several other techniques can be applied for aligning nanotubes. According to one embodiment, an electric field can be applied to control the growth direction for the alignment of suspended SWNTs or nanotubes on a surface. The alignment of the nanotubes can result from the high polarizability of nanotubes. According to another embodiment, heating silicon carbide at 1500° C. under a high vacuum can produce a SWNT network with a desired orientation.

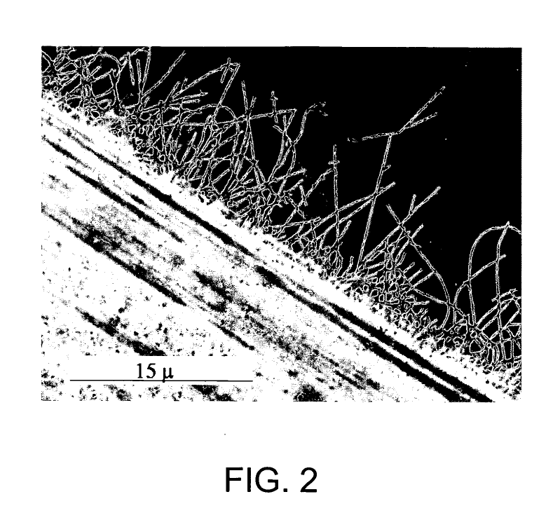

Nanotubes grown utilizing a fast heating method such as the method described with respect to FIGS. 1A-1C can yield nanotube lengths greater than one centimeter. In contrast, the application of a slow heating process to grow nanotubes does not grow nanotubes as long as a fast heating process. In a slow heating process, for example, the substrate sample can be positioned at the center of the furnace while the furnace is heated to about 900° C. in about 10 to 30 minutes. For example, FIG. 2 illustrates a scanning electron microscope (SEM) image of a side view of a substrate having SWNTs fabricated thereon. The SWNTs shown in FIG. 2 have been produced according to a slow heating process. SEM images can be captured by the PHILIPS® XL-30 FEG apparatus, available from Koninklijke Philips Electronics N.V. of the Netherlands. Under these magnification and imaging conditions, the nanotubes are shown as bright lines under SEM. The nanotubes were grown under CO/H₂ flow (800/200 sccm) at 900° C. for 10 minutes. Fe/Mo nanoparticles patterned by photolithography were used as catalyst. The SWNTs are randomly oriented and less than 20 micrometers in length.

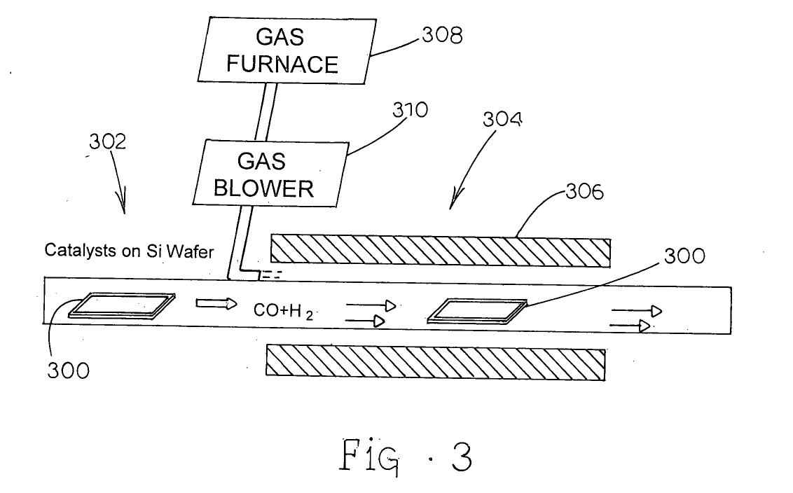

A fast heating process utilizing a suitable feeding gas flow and reaction temperature can produce ultralong and well-aligned SWNT arrays. FIG. 3 is a schematic diagram of exemplary stages of a substrate 300 undergoing a fast heating process. At a pre-heating stage generally designated 302, catalysts (such as catalysts 102 shown in FIGS. 1B and 1C) can be dispersed on substrate 300. Next, at a heating stage generally designated 304, substrate 300 can be moved by transferring a quartz tube (not shown) containing substrate 300 to the center of the heating zone of furnace 306. Alternatively, furnace 306 can be moved with respect to substrate 300 such that substrate 300 is positioned in the center of the heating zone of furnace 306. The heating can occur at about 900° C. for between about 10 and 20 minutes for growing nanotubes (such as nanotubes 108 shown in FIG. 1C) on substrate 300. During heating, substrate 300 can be subjected to gas flow with a gas, such as CO/H₂. The gas can be preheated to about 700° C. via a gas furnace 308 prior to applying the gas to substrate 300. The gas can be received by gas blower 310 and directed in a desired direction for the alignment of the nanotubes as substrate 300 is heated by furnace 306. Furnace 306 can be preheated to 900° C. prior to moving substrate 300 into the heating zone. Next, substrate 300 can be moved out of furnace 300.

The use of a fast heating process as described above can result in nanotubes growing at a rate greater than 3.3 micrometers per second. This fast growth rate can ensure that nanotubes are “sliding” along the substrate or moving just above the substrate without strong interaction with the underlying substrate. When the nanotube growth rate is slow, the nanotubes can be shorter and interact with the substrate to make it less likely that the nanotubes align with the gas flow. The fast growth of nanotubes under the fast heating process can also be due to the creation of convection waves, which lift the nanotubes off the surface in the initial seconds of heating and keep the nanotubes growing up from the surface. The nanotubes can be subsequently caught by the wind of the gas flow and trail downstream, which leads to the great length and alignment of the nanotubes.

FIG. 4A illustrates an SEM image of a top view of a substrate (such as substrate 100 shown in FIG. 1C) with SWNTs (such as nanotubes 108 shown in FIG. 1C) fabricated thereon, wherein the SWNTs have been produced according to a fast heating embodiment with CO/H₂ flow and a reaction temperature of about 900° C. Under these magnification and imaging conditions, the nanotubes are shown as bright lines under SEM. FIG. 4A shows that the nanotubes are aligned and includes a 200 micrometer scale for size reference. The white arrow indicates the direction of gas flow when growing the nanotubes. FIG. 4B is a composite of different SEM images showing two millimeter long nanotubes.

FIG. 4C is another SEM image of a magnified top view of SWNTs aligned along a controlled angle (about 300) with respect to the edge of a catalyst island 200. The image shown in FIG. 4C includes a 150 micrometer scale for size reference. The white arrow indicates the direction of gas flow when the nanotubes were grown. The heights of the nanotubes according to this embodiment can be between about 1 and 2.5 nanometers. A substantial number of the nanotubes can grow along one direction (indicated by a white arrow), the direction of the gas flow. One end of the nanotubes can be embedded within the catalyst island (such as catalyst island 200 shown in FIG. 4C). The opposing free end of the nanotube can extend between several hundred micrometers and a few millimeters along the growth direction, or direction of gas flow.

Referring again to FIG. 4A, some of the nanotubes, particularly lengthy nanotubes, can have both of their ends embedded within a catalyst island to form a u-shaped structure. The u-shaped structure can be caused by the pinning of the free end of the nanotube within the catalyst island due to local turbulent flow during the early growth stage when the nanotube was still relatively short. The short nanotube with both ends pinned to the catalyst island can continue to grow to produce the long u-shaped nanotubes shown in FIG. 4B. Many of the SWNTs are relatively straight and have a length of several hundred micrometers after about 10 minutes of growth. The growth rate can be about 200 micrometers per minute. Such long nanotubes can facilitate the evaporation of multiple metal electrode on a single nanotube. Thus, multiple devices can be created on the same nanotube along its length.

The increased nanotube length results in added processability, which can facilitate large-scale device fabrication. For example, it is easier to add/evaporate multiple metal electrodes onto a single nanotube and, if desired, such long nanotubes can be easily cut into desirable lengths using known cutting methods. FIG. 4D is an SEM image of a top view of nanotubes that have been cut by running a blade across the nanotubes. The use of a macroscale physical cutting technique to control the length of individual SWNTs provides a convenient, flexible, and readily scalable way of achieving desired nanotube lengths. A fabrication method can be implemented for individually cutting nanotube arrays of any size from a larger array with a blade, saw, or some other suitable physical instrument. The extreme length and alignment of these nanotubes makes it possible to readily incorporate them into devices by micropatterning, macroscale machining, and other suitable top-down processing techniques.

Length control of nanotubes can also be achieved by patterning catalyst islands beside one another with predetermined separations. When nanotubes are directed to grow towards an adjacent catalyst island, the nanotubes stop growing upon reaching the adjacent catalyst island. To utilize such properties, catalyst islands with predetermined separations can be fabricated using photolithography techniques on substrates, such as silicon wafers. FIG. 4E illustrates an SEM image of a top view of nanotubes extending between catalyst islands. The nanotubes shown in FIG. 4E grew from the edge of one catalyst island and terminated at the edge of another catalyst island downstream. The lengths of the nanotubes can be determined by the separation of the catalyst islands.

FIGS. 4F and 4G illustrate SEM images of a top view of a catalyst island pattern on a SiO₂/Si wafer before and after nanotube growth, respectively. The catalyst islands are photolithographically patterned. Referring now to FIG. 4F, the nanotubes are well-oriented and grow from the edge of the catalyst islands where space for long nanotube growth is available. On top of the catalyst islands, only a very thin layer of short, randomly oriented nanotubes are formed. The distance between the catalyst islands can determine the length of the aligned nanotubes, because the nanotube growth terminates once the nanotubes meet another catalyst island. Nanotubes can grow up to several millimeters in length and along the direction of gas flow at the farthest edge of the catalyst islands. Referring to FIG. 4H, another SEM image shows that the nanotubes terminate at a free end because there is no additional catalyst pattern downstream of the gas flow exists.

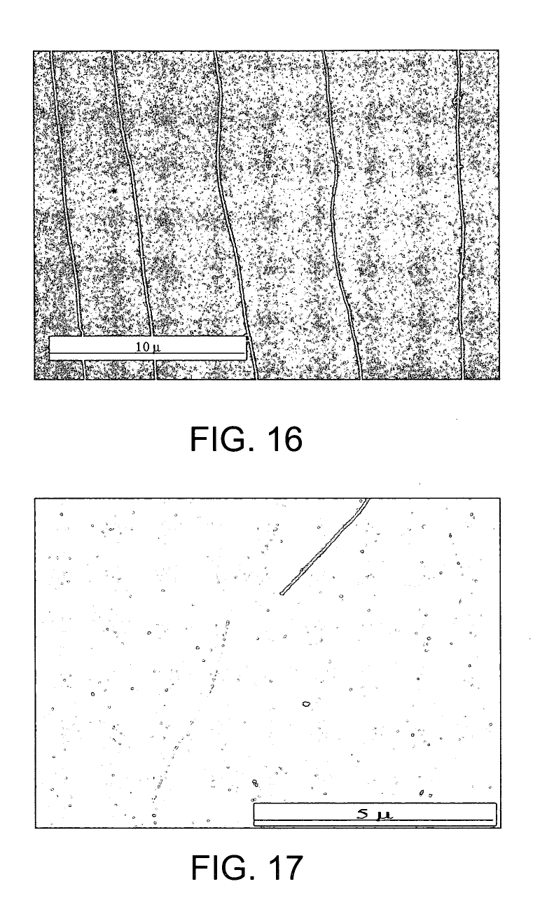

FIGS. 4I-4N illustrate different SEM images of SWNTs attached to a substrate. Referring specifically to FIG. 41, SWNTs are shown grown using a fast heating process with Fe/Mo nanoparticles. The SWNTs were grown in a direction indicated by the white direction arrow. The inset component is a magnified view. FIG. 4J illustrates an SEM image of a 2.1 millimeter straight SWNT grown according to a fast heating process. FIG. 4K illustrates several individual SWNTs aligned parallel to one another grown according to a fast heating process. The SWNTs are about 3.9 millimeters in length. FIG. 4L illustrates several SWNTs grown using an Fe/Mo molecular cluster, CO/H₂ gas, at 900° C. for about 10 minutes. FIG. 4M illustrates several long SWNTs grown using Fe/Mo nanoparticles, C H₂OH/H₂/Ar, at about 900° C. for about 10 minutes. FIG. 4N illustrates random short SWNTs grown with a slow heating technique. The SWNTs were grown using Fe/Mo nanoparticles, CO/H₂ as feeding gas, at about 900° C. for about 10 minutes.

FIG. 5 is an atomic force microscopy (AFM) image showing SWNTs grown using a fast heating process. AFM images can be captured by the NANOSCOPE® IIIA system with a multi-mode AFM and in tapping mode available from Veeco Instruments Inc. of Woodbury, N.Y. AFM height measurements indicate that the nanotubes can have diameters between about 0.8 and 2.5 nanometers. FIG. 6 is a Raman spectrum chart of the as-synthesized ultralong SWNT arrays. A G-mode vibration can be observed at 1586 and 1563 cm⁻¹, which relates to the in-plane vibration of a highly curved graphene sheet. The characteristic SWNT radial breathing mode can be observed at 181 cm⁻¹. Based on the equation γ[cm⁻¹]=223.75d, the average diameter of the nanotube is calculated to be about 1.25 nanometers. Additionally, based on Raman measurements, the length of nanotubes can be as long as about 1.5 centimeters by using a 20 minute growth with methane as feeding gas. Raman spectra can be collected from a quartz substrate using a DILOR Raman spectrometer with triple spectrograph (available from Dilor SA of France). The excitation wavelength can be 514.5 nanometers with an Ar-ion laser source at a power of about 120 milliwatts. The beam size can be about 3 micrometers in diameter.

### Crossed Networks of SWNT Arrays

According to another embodiment, crossed networks of SWNT arrays can be grown on one or more substrates. Techniques according to this embodiment can be used to assemble SWNTs and other nanowires into multi-terminal devices and complex circuits. FIGS. 7A and 7B illustrate different perspective views of a crossed network of SWNT arrays. Referring specifically to FIG. 7A, crossed network of SWNT arrays, generally designated 700, can be attached to a surface 702 of a substrate 704. SWNT arrays 700 can include a first set of nanotubes 706 extending parallel to one another across surface 702. SWNT arrays 700 can also include a second set of nanotubes 708 extending parallel to one another and perpendicular to nanotubes 706. Alternatively, nanotubes 706 and 708 can be angled at another suitable angle with respect to each other.

Referring now to FIG. 7B, a crossed network of SWNT arrays, generally designated 710, are attached to a substrate 712. Substrate 710 can include a number of suspension structures 714 fabricated on surface 716 via a suitable process known to those of skill in the art. SWNT arrays 710 can include a first set of nanotubes 718 extending parallel to one another across surface 716 and between suspension structures 714. SWNT arrays 710 can also include a second set of nanotubes 720 extending parallel to one another, along the top of suspension structures 714, perpendicular to nanotubes 718.

A crossed network of SWNT arrays can be fabricated via a two-step process. In this process, a first set of nanotubes are first grown along one direction and then a second set of nanotubes are grown in another direction over the first set of nanotubes to result in a two-dimensional network of SWNTs. Referring to FIGS. 8A-8D, views of different stages in the fabrication of crossed network of SWNT arrays are illustrated. FIG. 8A illustrates a top view of a substrate 800 for fabrication of a crossed network of SWNT arrays. A first set of catalysts, generally designated 802, can be dispersed or patterned on surface 804 of substrate 800. Catalysts 802 can be positioned parallel to a broken line 806.

Referring to FIG. 8B, a top view of surface 804 during the synthesis of nanotubes 808 from catalysts 802 is illustrated. Nanotubes 808 can be grown in a direction indicated by direction arrow D1 by feeding a gas of CO/H₂ mixture over catalysts 802 in a direction D1. Nanotubes 808 are grown in a direction D1, orthogonal to the alignment of catalysts 802, for fabricating a set of parallel nanotubes. Referring to FIG. 8C, a top view of surface 804 subsequent to dispersing with a second set of catalysts, generally designated 810 on surface 804. Catalysts 802 can be positioned parallel to a broken line 812, about perpendicular to the alignment of catalysts 802 aligned along broken line 806.

Referring to FIG. 8D, a top view of surface 804 during the synthesis of another set of nanotubes 814 from catalysts 802 is illustrated. Nanotubes 808 can be grown in a direction indicated by direction arrow D2 by feeding a gas of CO/H₂ mixture over catalysts 810 in a direction D2. Nanotubes 814 are grown in a direction D2, perpendicular to the alignment of nanotubes 808, for forming a crossed network of SWNT arrays. Alternatively, the alignment of nanotubes 808 with nanotubes 814 can be at any suitable angle.

FIG. 9A is an SEM image of a top view of a substrate having a two-dimensional nanotube network fabricated thereon. FIG. 9A also includes a 150 micrometer scale for size reference. The image is a low magnification image showing a 400×300 μm² cross-network architecture.

FIG. 9B is another SEM image of a magnified top view of the SEM image shown in FIG. 9A. The image shows a 3×2 SWNT network. The two sets of nanotubes are shown having an angle about 90° with respect to one another. Alternatively, the nanotubes can be any other desired angle with respect to one another by applying the gas flow in the second step at the desired angle with respect to the gas flow in the first step.

FIGS. 10A-10C are SEM images of different multi-layer crossed network of SWNTs. FIG. 10A provides a 300 micrometer scale is provided for reference. The shown area is about 0.85×0.65 millimeters. This structure was fabricated on a flat substrate via a two-step, bidirectional growth process. To fabricate this structure, nanotubes were first grown along one direction and then the sample was rotated 90° before the second layer of SWNTs was grown under similar conditions. This two-step growth process can result in the formation of a two-dimensional nanotube array. FIG. 10B is another SEM image of another multi-layer crossed network of SWNTs. A 300 micrometer scale is provided for reference. The crossed network structure is about 4×2 millimeters. FIG. 10C is an SEM image of nanotube arrays with a 60° angle between one another.

In the examples shown in FIGS. 10A-10C, the parallel nanotube arrays are on the same flat surface and the crossed nanotubes are in Van der Waals contact, forming multi-junctions that can be suitable for large-scale, multi-junction electronic devices.

Suspended, crossed multi-SWNT architectures can also be fabricated as discussed above that can be amenable to large-scale integration of many suspended nanotube devices. For example, suspended, crossed nanotube arrays can exhibit bistable, electronically switchable ON/OFF states, which can be used for nanoscale, non-volatile random access memories for molecular computing applications. FIGS. 10D and 10E are AFM images of a top view of a suspension structure on a substrate surface before and after, respectively, different suspended, crossed nanotube arrays are grown. These nanotube architectures can be fabricated by growing a nanotube array on a patterned Si/SiO₂ surface. The first nanotube layer was selectively oriented parallel to the channel direction. The second nanotube layer was oriented perpendicular to the channel direction. This can result in the shown large-scale, suspended nanotube array. The patterned Si/SiO₂ wafer can be generated by the combination of soft lithography and chemical etching.

Referring specifically to FIG. 10E, nanotubes can follow the channels. The channels can guide the growth of the nanotubes if they have sufficient depth. The second layer of nanotubes can then be grown on top of the pattern with the second layer's growth direction being perpendicular to the direction of the channels. The nanotubes can be suspended by the patterned Si/SiO₂ ridges of the suspension structures. FIG. 10F is a magnified AFM image of FIG. 10E. These types of structures can be used as functional networks and as building blocks for molecular electronics.

### “Kite-Process” for Growing Nanotubes

In a nanotube fast heating process, the orientation of nanotubes can be controlled by directing the flow of gas during growth. This implies that the gas flow may be floating the nanotubes during the growth of the nanotubes. For example, FIGS. 11A and 11B illustrate exemplary SEM images showing nanotubes that have grown over a barrier on the substrate and across trenches. FIGS. 11A and 11B include a 2 micrometer and a 75 micrometer distance scale, respectively, for size reference. Catalysts were deposited in the trench with a depth of 800 nanometers fabricated on a silicon wafer. Several of the nanotubes shown in FIG. 11B grew over the barrier with a height of 800 nanometers. These images show that in the initial stages of growth, the nanotubes grew up from the substrate surface. Growing nanotubes can also be deflected when reaching a barrier on the substrate such that the nanotube is not straight.

The “kite-mechanism” for growing nanotubes can be utilized to grow long nanotubes and float the nanotubes over structures. FIG. 12 is an AFM image showing a long nanotube having a nanoparticle at its tip. FIG. 12 includes a distance scale of two micrometers for size reference. The size of the nanoparticle tip is typically larger than the nanotube diameter, thus providing the appearance of a flying kite when the nanotube is raised due to gas flow. The larger size of the nanotube tip than the nanotube diameter can be due to the amorphous carbon coating around the catalyst during the cooling process.

FIGS. 13A-13D illustrate different stages in the fabrication of a nanotube on a substrate for demonstrating the “kite-mechanism”. Referring specifically to FIG. 13A, a cross-sectional side view of a substrate 1300 having a catalyst particle 1302 deposited thereon is illustrated. Next, the samples were fast heated to reaction temperature (for example, 900° C.) over a very short time period.

Referring to FIG. 13B, a cross-sectional side view of substrate 1300 with heat and a laminar flow applied in a direction parallel to the top surface of substrate 1300. The flow is directed in a direction indicated by direction arrows D1. Due to the heating and laminar flow, catalyst particle 1302 can form a nanotube 1304. As the result of fast heating, substrate 1300 and the surrounding gas can be heated up at different speeds and have different temperatures during the heating process before the thermal equilibrium was reached. A convection flow can be formed due to the temperature difference between substrate 1300 and the gas and flow in the direction indicated by direction arrows D2. Such a convection flow can lift nanotube 1304 up with catalyst particle 1302 on the tip of nanotube 1304. Due to the convection flow, nanotube 1304 can grow in a direction away from substrate 1300 and leave the surface where the flow velocity of the feeding gas was slow.

Referring to FIG. 13C, a cross-sectional side view of substrate 1300 with nanotube 1304 flowing in the direction of laminar flow is illustrated. The horizontal laminar flow of the feeding gas above the substrate surface can carry nanotube 1304 while it is growing and align nanotube 1304 along the direction of gas flow (i.e., the direction indicated by direction arrow D1). During growth, the active ends of the nanotubes were always floating while the sections close to the original sites where the catalysts used to be might forming Van der Waals contact with the substrate. Referring to FIG. 13D, a cross-sectional side view of substrate with nanotube 1304 growing until it contacted the surface of substrate 1300 or termination of carbon source.

The kite-mechanism can explain the growth of long and oriented nanotubes. The difference in lengths between nanotubes grown using different CVD processes can be explained by taking into account of the difference between “tip-growth” and “base-growth” mechanisms. In “base-growth” mechanism, the catalysts stay on the substrate throughout the growth process.

There may be two reasons explaining the limited growth of the nanotubes. One is the termination of nanotube growth because of the strong Dan der Waals interaction between the nanotubes and the substrate surface when the nanotubes reach certain length. For base growth mechanism, since the whole nanotubes slides on the surface, once they rest on the surface, the nanotube/substrate interaction can increase as a function of the length. The growth would eventually stop when the force needed to move the whole nanotube became energetically unfavorable. For tip-growth mechanism, this would not present a problem since the catalysts were on the tip of the nanotubes.

The other reason for the length difference between the two growth methods may be the diffusion of the feeding gas to the surface of the catalysts.

The flow rate of feeding gas on the substrate surface is much lower than above the surface. Using the standard flow dynamic calculation, the velocity profile of a flat plate in free flow can be described using a “boundary layer” of slow moving fluid that builds up from the front to the back of the plate. The edge of this boundary layer is normally defined as the point at which flow is 99% of the free-stream velocity, and its height is approximately 5 times the distance from the front edge of the plate divided by the square root of the Reynolds number.

FIG. 14 is a chart of height versus distance along a substrate surface showing the flow velocity of a nanotube distributed above a flat substrate. At any specific position on the substrate, the flow velocity is a function of the height. Close to the surface, the velocity profile is a linear function of the height, and its slope is determined by the equation u=U₀*0.332*H(Reₓ/x)^{1/2} (wherein u is the local flow velocity, U₀ is free stream velocity calculated from the overall flow rate, H is the height from the surface of the wafer, x is the distance from the edge of the Si wafer and Reₓ is Reynolds number defined as U₀*x/ν with ν being the dynamic viscosity of the gas).

FIG. 15 is a plot chart of flow velocity as a function of height at two different locations on a flat substrate. The calculation shows that at the surface of a flat substrate the gas flow velocity is very low. If the catalysts stayed on the surface of the substrate, the only mechanism for new precursor molecule to reach the catalysts was through diffusion. The calculation also showed that only when the nanotubes grew up into the high velocity region, the flow of the gas could apply enough force to align the nanotubes along the flow direction.

Finally, the kite-mechanism can also be used to explain the low growth efficiency of the long nanotubes. FIG. 16 is an SEM image of a high density of well-oriented SWNT arrays, including a 10 micrometer scale for size reference. As shown, the density for these long nanotube arrays is about 5 micrometers apart. There are several possible reasons for this low efficiency. First, all nanotubes may not be grown by the kite-mechanism. Only a small fraction of nanoparticles having weak interaction with surface initiated nanotubes under tip-growth mechanism, while the majority of the catalysts still nucleate nanotubes under the “base-growth” mechanism. This hypothesis was confirmed by SEM and AFM observations that there were many short and randomly oriented nanotubes close to the patterned catalyst area. FIG. 17 is an AFM image of nanotubes without catalysts on their tips and near a catalyst island, including a 5-micrometer scale for size reference. These short nanotubes are grown from the base-growth mechanism as demonstrated by observation of the AFM image that these nanotubes do not have nanoparticles on their tips. Second, some of nanotubes stop growing because the growing ends landed on the substrate rather than floating in the gas flow. This can explain why the long nanotubes have different lengths ranging from several hundreds microns to millimeters. Third, the supply of carbon source has to match the growth rate of nanotube. This can be particularly important for the initial growth step. The ratio of CO/H₂ can be very important for the growth of long nanotubes.

It will be understood that various details of the invention may be changed without departing from the scope of the invention. Furthermore, the foregoing description is for the purpose of illustration only, and not for the purpose of limitation, as the invention is defined by the claims as set forth hereinafter.

1. A method of fabricating a nanotube on a substrate, the method comprising:
(a) attaching a catalyst to a substrate;
(b) heating the catalyst to a predetermined temperature such that a nanotube grows from the catalyst; and
(c) directing a feeding gas over the catalyst in a predetermined direction such that the nanotube grows in the predetermined direction.

2. The method of claim 1 wherein the attaching step comprises patterning the substrate.

3. The method of claim 2 wherein patterning the substrate comprises photolithographic patterning.

4. The method of claim 1 wherein the attaching step comprises dispersing the catalyst on the substrate.

5. The method of claim 1 wherein the attaching step comprises depositing the catalyst on the substrate.

6. The method of claim 1 wherein the catalyst is composed of a material selected from the group consisting of iron, molybdenum, platinum, and combinations thereof.

7. The method of claim 1 wherein the catalyst is monodispersed.

8. The method of claim 1 wherein the catalyst is between about 1 and 6 nanometers in diameter.

9. The method of claim 1 wherein the substrate is composed of a material selected from the group consisting of silicon oxide, silicon, quartz, and combinations thereof.

10. The method of claim 1 wherein the substrate comprises a silicon oxide layer for attachment of the catalyst.

11. The method of claim 10 wherein the silicon oxide layer is about 100 nanometers thick.

12. The method of claim 1 wherein the surface of the substrate comprises a silica layer for attachment of the catalyst.

13. The method of claim 1 wherein the predetermined temperature is between about 800° C. and 1050° C.

14. The method of claim 1 wherein the catalyst is heated between about 10 and 20 minutes.

15. The method of claim 1 wherein the feeding gas is composed of a material selected from the group consisting of carbon, hydrogen, carbon monoxide, hydrocarbons, alcohols, hydrocarbon/H₂ mixture, alcohol/H₂ mixture, and combinations thereof.

16. The method of claim 1 comprising heating the feeding gas to about 700° C. before directing the feeding gas over the catalyst.

17. The method of claim 1 further including cutting the nanotubes to a predetermined length.

18. The method of claim 1 applying an electric field to align the nanotubes in the predetermined direction.

19. The method of claim 1 applying a magnetic field to align the nanotubes in the predetermined direction.

20. The method of claim 1 applying a gravity field to align the nanotubes in the predetermined direction.

21. A method of fabricating a nanotube on a substrate, the method comprising:
(a) attaching a catalyst to a substrate;
(b) heating the catalyst to between about 800° C. and 1050° C. between about 10 and 20 minutes such that a nanotube grows from the catalyst; and
(c) directing a feeding gas over the catalyst in a predetermined direction such that the nanotube grows in the predetermined direction.

22. A system for fabricating a nanotube on a substrate, the system comprising:
(a) a substrate comprising a catalyst attached thereto;
(b) a furnace operable to heat the catalyst to a predetermined temperature such that a nanotube grows from the catalyst; and
(c) a gas blower operable to direct a feeding gas over the catalyst in a predetermined direction such that the nanotubes grow in the predetermined direction.

23. The system of claim 22 wherein the catalyst is composed of a material selected from the group consisting of iron, molybdenum, platinum, and combinations thereof.

24. The system of claim 22 wherein the catalyst is monodispersed.

25. The system of claim 22 wherein the catalyst is between about 1 and 6 nanometers in diameter.

26. The system of claim 22 wherein the substrate is composed of a material selected from the group consisting of silicon oxide, silicon, quartz, and combinations thereof.

27. The system of claim 22 wherein the substrate comprises a silicon oxide layer for attachment of the catalyst.

28. The system of claim 27 wherein the silicon oxide layer is about 100 nanometers thick.

29. The system of claim 22 wherein the surface of the substrate comprises a silica layer for attachment of the catalyst.

30. The system of claim 22 wherein the predetermined temperature is between about 800° C. and 1050° C.

31. The system of claim 22 the catalyst is heated between about 10 and 20 minutes.

32. The system of claim 22 wherein the furnace is a first furnace, and comprising a second furnace operable to heat the feeding gas to about 700° C. prior to the first furnace directing the feeding gas over the catalyst.

33. The system of claim 22 wherein the feeding gas is composed of a material selected from the group consisting of carbon, hydrogen, carbon monoxide, hydrocarbons, alcohols, hydrocarbon/H₂ mixture, alcohol/H₂ mixture, and combinations thereof.

34. The system of claim 22 comprising a cutting tool for cutting the nanotubes to a predetermined length.

35. A system for fabricating a nanotube on a substrate, the system comprising:
(a) a substrate comprising a catalyst attached thereto; and
(b) a furnace operable to heat the catalyst to between about 800° C. and 1050° C. for between about 10 and 20 minutes such that a nanotube grows from the catalyst; and
(c) a gas blower operable to direct a feeding gas over the catalyst in a predetermined direction such that the nanotubes grow in the predetermined direction.

36. A method of fabricating a nanotubes on a substrate, the method comprising:
(a) attaching a first catalyst to a substrate;
(b) heating the first catalyst to a first predetermined temperature such that a first nanotube grows from the first catalyst;
(c) directing a first feeding gas over the first catalyst in a first predetermined direction such that the first nanotube grows in the first predetermined direction;
(d) attaching a second catalyst to the substrate;
(e) heating the second catalyst to a second predetermined temperature such that a second nanotube grows from the first catalyst; and
(f) directing a second feeding gas over the second catalyst in a second predetermined direction such that the second nanotube grows in the second predetermined direction, wherein the second predetermined direction is a different direction than the first predetermined direction.

37. The method of claim 36 wherein the first and second catalysts are composed of a material selected from the group consisting of iron, molybdenum, platinum, and combinations thereof.

38. The method of claim 36 wherein the first and second catalysts are monodispersed.

39. The method of claim 36 wherein the first and second catalysts are between about 1 and 6 nanometers in diameter.

40. The method of claim 1 wherein the substrate is composed of a material selected from the group consisting of silicon oxide, silicon, quartz, and combinations thereof.

41. The method of claim 36 wherein the substrate comprises a silicon oxide layer for attachment of the catalyst.

42. The method of claim 41 wherein the silicon oxide layer is about 100 nanometers thick.

43. The method of claim 36 wherein the surface of the substrate comprises a silica layer for attachment of the catalyst.

44. The method of claim 36 wherein the first and second predetermined temperatures are between about 800° C. and 1050° C.

45. The method of claim 36 wherein the first and second catalysts are heated between about 10 and 20 minutes.

46. The method of claim 36 wherein the first and second feeding gases are composed of a material selected from the group consisting of carbon, hydrogen, carbon monoxide, hydrocarbons, alcohols, hydrocarbon/H₂ mixture, alcohol/H₂ mixture, and combinations thereof.

47. The method of claim 36 comprising heating the first and second feeding gases to about 700° C. before directing the first and second feeding gases over the first and second catalyst, respectively.

48. A system for fabricating nanotubes on a substrate, the system comprising:
(a) a substrate comprising a first and second catalyst attached thereto;
(b) a furnace operable to heat the first catalyst to a first predetermined temperature such that a first nanotube grows from the first catalyst, and operable to heat the second catalyst to a second predetermined temperature such that a second nanotube grows from the second catalyst; and
(c) a gas blower operable to direct a first feeding gas over the first catalyst in a first predetermined direction such that the first nanotube grows in the first predetermined direction, operable direct a second feeding gas over the second catalyst in a second predetermined direction such that the second nanotube grows in the second predetermined direction, and wherein the second predetermined direction is a different direction than the first predetermined direction.

49. The system of claim 48 wherein the first and second catalysts are composed of a material selected from the group consisting of iron, molybdenum, platinum, and combinations thereof.

50. The system of claim 48 wherein the first and second catalysts are monodispersed.

51. The system of claim 48 wherein the first and second catalysts are between about 1 and 6 nanometers in diameter.

52. The system of claim 48 wherein the substrate is composed of a material selected from the group consisting of silicon oxide, silicon, quartz, and combinations thereof.

53. The system of claim 48 wherein the substrate comprises a silicon oxide layer for attachment of the catalyst.

54. The system of claim 53 wherein the silicon oxide layer is about 100 nanometers thick.

55. The system of claim 48 wherein the surface of the substrate comprises a silica layer for attachment of the catalyst.

56. The system of claim 48 wherein the first and second predetermined temperatures are between about 800° C. and 1050° C.

57. The system of claim 48 wherein the first and second catalysts are heated between about 10 and 20 minutes.

58. The system of claim 48 wherein the first and second feeding gases are composed of a material selected from the group consisting of carbon, hydrogen, carbon monoxide, hydrocarbons, alcohols, hydrocarbon/H₂ mixture, alcohol/H₂ mixture, and combinations thereof.

59. The system of claim 48 comprising heating the first and second feeding gases to about 700° C. before directing the first and second feeding gases over the first and second catalyst, respectively.

60. A method of fabricating nanotubes on a substrate, the method comprising:
(a) providing a substrate comprising a surface and a plurality of suspension structures attached to the surface, wherein the suspension structures are separated by an area of the surface of the substrate;
(b) attaching a first plurality of catalysts to the surface area of the substrate between the separated suspension structures;
(c) heating the first plurality of catalysts to a first predetermined temperature such that a first plurality of nanotubes grow from the first plurality of catalysts;
(d) directing a first feeding gas over the first plurality of catalysts in a first predetermined direction such that the first plurality of nanotubes grow in the first predetermined direction;
(e) attaching a second plurality of catalysts to the plurality of suspension structures;
(f) heating the second plurality of catalysts to a second predetermined temperature such that a second plurality of nanotubes grow from the first plurality of catalysts; and
(g) directing a second feeding gas over the second plurality of catalysts in a second predetermined direction such that the second plurality of nanotubes grow in the second predetermined direction, wherein the second predetermined direction is a different direction than the first predetermined direction.

61. The method of claim 60 wherein the first and second catalysts are composed of a material selected from the group consisting of iron, molybdenum, platinum, and combinations thereof.

62. The method of claim 60 wherein the first and second predetermined temperatures are between about 800° C. and 1050° C.

63. The method of claim 60 wherein the first and second catalysts are heated between about 10 and 20 minutes.

64. The method of claim 60 wherein the first and second feeding gases are composed of a material selected from the group consisting of carbon, hydrogen, carbon monoxide, hydrocarbons, alcohols, hydrocarbon/H₂ mixture, alcohol/H₂ mixture, and combinations thereof.

65. The method of claim 60 comprising heating the first and second feeding gases to about 700° C. before directing the first and second feeding gases over the first and second catalyst, respectively.

66. The method of claim 60 wherein the suspension structures extend in a substantially straight direction and about parallel to one another along the surface of the substrate.

67. The method of claim 61 wherein the first gas flow is in the substantially straight direction of the suspension structures such that the first plurality of nanotubes grow along the surface area of the substrate between the separated suspension structures.

68. The method of claim 67 wherein the second gas flow is in a direction about perpendicular to the substantially straight direction of the suspension structures such that the second plurality of nanotubes grow across the separated suspension structures.
